(19) United States
(12) Patent Application Publication
(10) Pub. No.: US 2024/0386156 A1
(43) Pub. Date: Nov. 21, 2024

(54) RECORDING MEDIUM AND COMPUTER

(71) Applicant: Rohm Co., Ltd., Kyoto (JP)

(72) Inventor: Naoyuki USAGAWA, Kyoto (JP)

(21) Appl. No.: 18/666,748

(22) Filed: May 16, 2024

(30) Foreign Application Priority Data
May 17, 2023 (JP) 2023-081587

(51) Int. Cl. G06F 30/17

(52) U.S. Cl. CPC G06F 30/17

(57) ABSTRACT

A recording medium is a non-transitory recording medium having a simulation program recorded thereon. The simulation program is a program configured to cause a computer to simulate operation of a motor control system. The simulation program is configured to cause the computer to generate a display signal for displaying a step-out error index indicating likelihood of the motor control system falling out of step.

### CROSS-REFERENCE TO RELATED APPLICATIONS

This nonprovisional application claims priority under 35 U.S.C. § 119 (a) on Patent Application No. 2023-081587 filed in Japan on May 17, 2023, the entire contents of which are hereby incorporated by reference.

### BACKGROUND OF THE INVENTION

### 1. Technical Field

The invention disclosed herein relates to a non-transitory recording medium having a simulation program recorded thereon, and a computer executing the simulation program.

### 2. Description of Related Art

A phenomenon called “step-out error” is observed in the behavior of motors. “Step-out error” refers to a phenomenon in which actual rotation of a motor fails to follow a control signal according to which the rotation of the motor should be controlled, so that the motor becomes uncontrollable.

By setting constants of a motor control system, it becomes possible to perform a simulation in which the behavior of a real machine is closely mimicked. Thus, there are cases where it is possible to determine occurrence of a step-out error also in a simulation.

### BRIEF DESCRIPTION OF THE DRAWINGS

FIG. 1 is a diagram schematically illustrating a configuration of a computer.

FIG. 2 is a flowchart schematically illustrating operation of a computer.

FIG. 3 shows graphs illustrating a first display example of a motor-rotation-speed simulation result and time-based change of a step-out error index.

FIG. 4 is a diagram illustrating a second display example of the motor-rotation-speed simulation result and the time-based change of the step-out error index.

FIG. 5 is a diagram illustrating a third display example of the motor-rotation-speed simulation result and the time-based change of the step-out error index.

FIG. 6 is a diagram illustrating a fourth display example of the motor-rotation-speed simulation result and the time-based change of the step-out error index.

### DETAILED DESCRIPTION

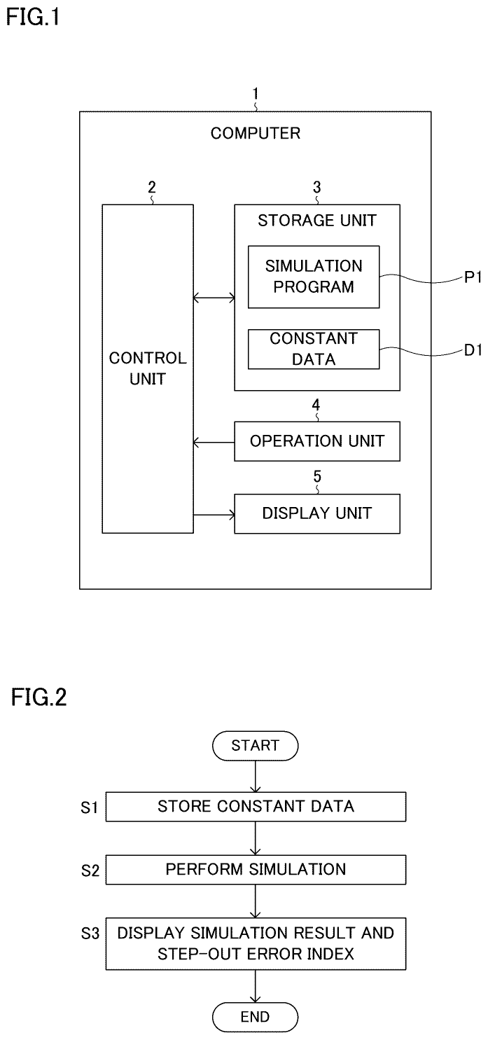

FIG. 1 is a diagram schematically illustrating a configuration of a computer 1 according to an embodiment. What is conceivable as a typical example of the computer 1 is a personal computer. However, the computer 1 is not limited to a personal computer, but may be, for example, a server, a cloud computer, etc.

The computer 1 includes a control unit 2, a storage unit, 3, an operation unit 4, and a display unit 5.

The control unit 2 is constituted of a central processing unit (CPU), for example. By the control unit 2 executing a simulation program P1 stored in the storage unit 3, a simulation is performed. Then, under control by the control unit 2, a simulation result is displayed on the display unit 5.

The storage unit 3 is constituted of, for example, a read only memory (ROM), a random access memory (RAM), etc. The storage unit 3 has the simulation program P1 and constant data D1 stored therein. The simulation program P1 is configured to cause a computer to simulate operation of a motor control system. The motor control system includes a motor and a motor driver configured to drive the motor. The constant data D1 includes constants for the motor and constants for the motor driver.

In the present embodiment, the motor control system is configured to detect a rotation position of a rotor based on an induced voltage generated at a stator coil of the motor. However, the motor control system may be configured to include a sensor (e.g., a Hall sensor or the like) for detecting the rotation position of the rotor. In the case where the motor control system is configured to detect the rotation position of the rotor based on an induced voltage generated at the stator coil of the motor, compared to a case where the motor control system includes a sensor for detecting the rotation position of the rotor, dependence on the motor constant becomes stronger, and there is a concern about degradation of robustness. Thus, if the motor control system is configured to detect the rotation position of the rotor based on an induced voltage generated at the stator coil of the motor, increased benefits can be obtained from being able to visualize whether control is being performed with a high possibility of a step-out error.

The operation portion 4 is constituted of, for example, a keyboard, a pointing device, a touch panel, etc. By a user operating the operation portion 4, the constant data D1, for example, is entered into the computer 1. When the constant data DI is entered into the computer 1, the control unit 2 causes the constant data DI to be stored in the storage unit 3.

The display unit 5 is constituted of a liquid crystal display device and the like, for example. The display unit 5 performs display based on a display signal output from the control unit 2.

FIG. 2 is a flowchart schematically illustrating operation of the computer 1. When the user performs, with respect to the operation portion 4, operation for instructing start-up of the simulation program P1, the control unit 2 starts the operation according to the flowchart of FIG. 2, and starts up the simulation program PI stored in the storage unit 3.

First, the control unit 2 causes the display unit 5 to display a message requesting the user to enter the constant data DI necessary for a simulation, and when the constant data DI is entered by the user by operating the operation unit 4, the control unit 2 causes the constant data D1 to be stored in the storage unit 3 (step S1).

Next, the control unit 2 performs a simulation regarding the operation of the motor control system (step S2). The control unit 2, when performing the simulation, calculates a step-out error index indicating likelihood of the motor control system falling out of step.

In the motor control system, a difference 40 is calculated between a detected rotation position of the rotor and a target rotation position of the rotor derived from a target rotation speed of the motor, and by the motor driver driving the motor such that the difference 40 becomes zero, the rotation speed of the motor is brought closer to the target rotation speed of the motor. In the present embodiment, a step-out error index is defined as a value corresponding to the number of consecutive times with which the difference Δθ becomes equal to or larger than a constant value. As the step-out error index becomes larger, the motor control system becomes more likely to fall out of step.

For example, in a case where γ represents the step-out error index of a case where the number of consecutive times is β with which the difference Δθ becomes equal to or larger than a constant value α, N×γ represents the step-out error index of a case where the number of consecutive times is N×β with which Δθ becomes equal to or larger than the constant value α. Note that periodic checks are conducted on whether or not the difference Δθ is equal to or larger than the constant value α.

Various known methods are available to calculate the difference Δθ, but in the present embodiment, in which the motor control system is configured to perform vector control, the difference Δθ is calculated according to the following expression.

$$\\ Δ θ = {tan}^{- 1} ( \frac{{V}_{d} - RId + ω {L}_{q} {I}_{q}}{{V}_{q} - RIq - ω {L}_{q} {I}_{d}} )$$

Vd: d-AXIS VOLTAGE VALUE
Vq: q-AXIS VOLTAGE VALUE
Id: d-AXIS CURRENT VALUE
Iq: q-AXIS CURRENT VALUE
Ld: d-AXIS INDUCTANCE
Lq: q-AXIS INDUCTANCE
ω: MOTOR ROTATION SPEED

In the present embodiment, as described above, the step-out error index is defined as a value corresponding to a number of consecutive times with which the difference Δθ becomes equal to or larger than a constant value. This is merely an example, however, and as long as the step-out error index indicates the likelihood of the motor control system falling out of step, the step-out index error may be other than a value corresponding to a number of consecutive times with which the difference Δθ becomes equal to or larger than a constant value.

Next, the control unit 2 generates a display signal for displaying the step-out error index, and outputs the display signal to the display unit 5. More specifically, the control unit 2 generates a display signal for displaying a simulation result of the operation of the motor control system and the step-out error index in graph form on the same screen, and feeds the display signal to the display unit 5. Then, the display unit 5 performs display based on the display signal output from the control unit 2. That is, the display unit 5 displays the simulation result and the step-out error index (step S3). When the display in step S3 is completed, the computer 1 finishes the operation that is based on the simulation program P1.

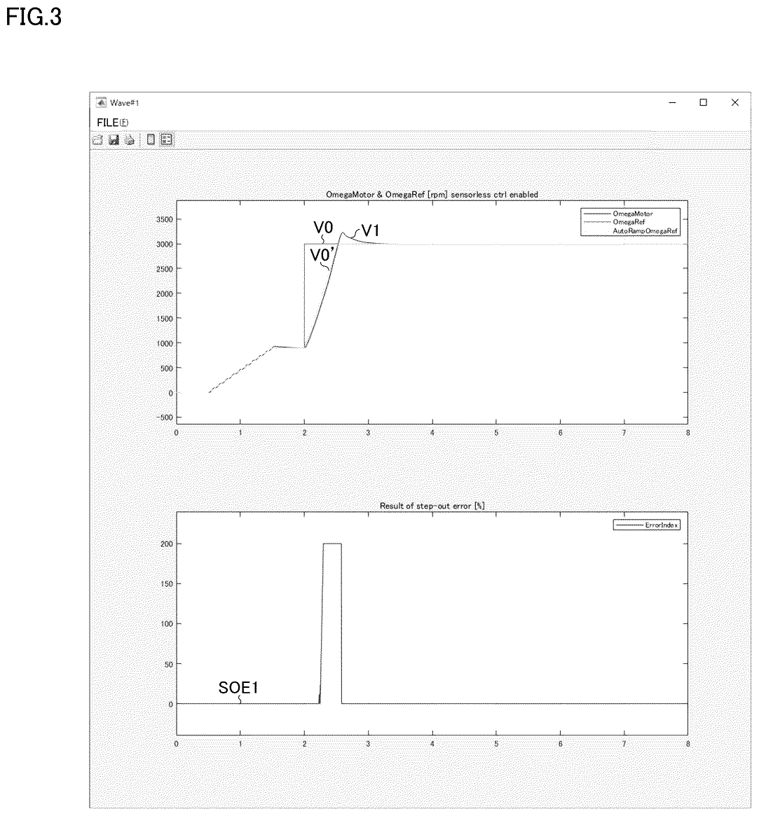

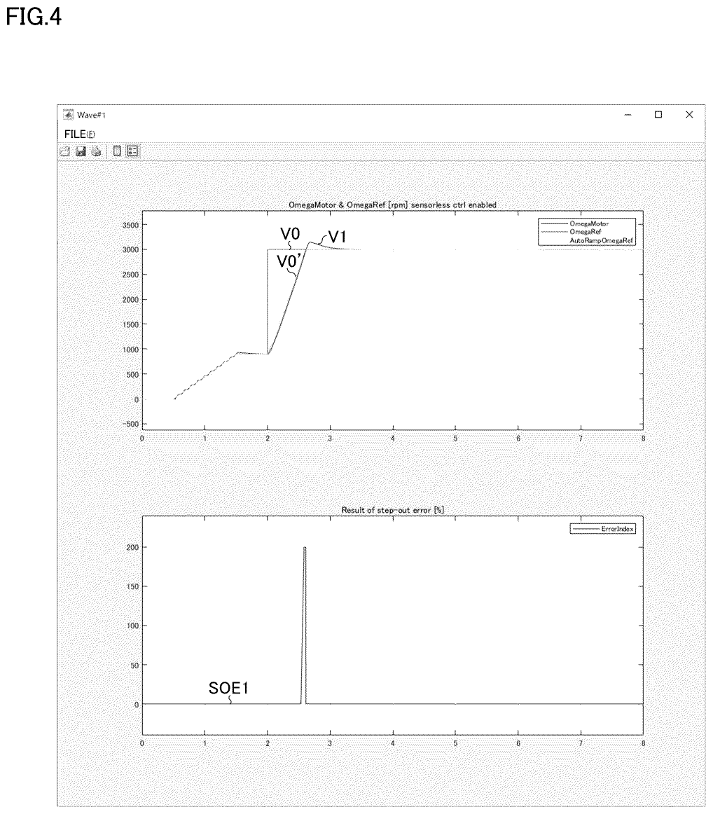

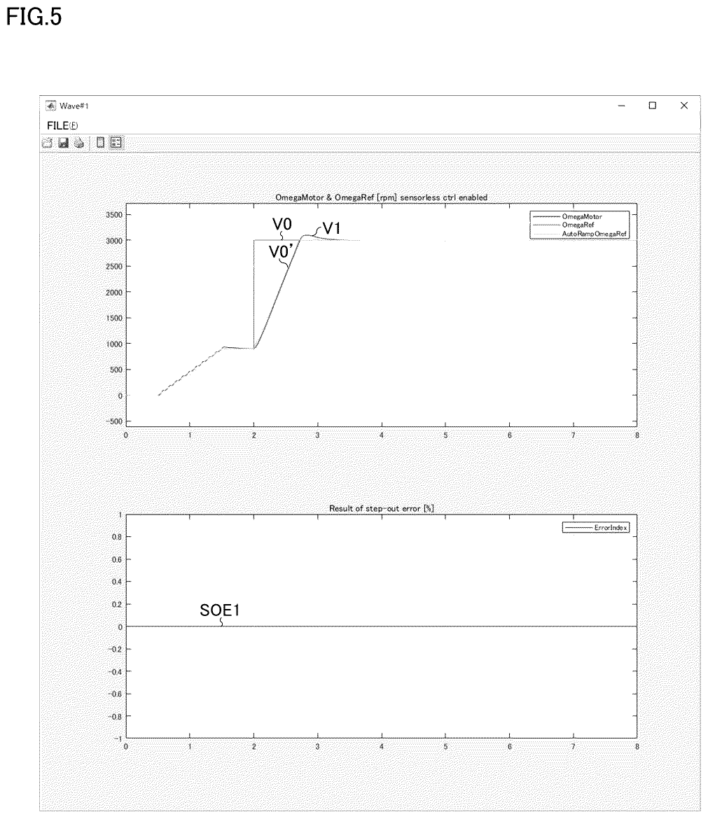

FIG. 3 is a diagram illustrating a first display example of a motor-rotation-speed simulation result and time-based change of the step-out error index. FIG. 4 is a diagram illustrating a second display example of the motor-rotation-speed simulation result and the time-based change of the step-out error index. FIG. 5 is a diagram illustrating a third display example of the motor-rotation-speed simulation result and the time-based change of the step-out error index.

The simulation results illustrated in FIG. 3 to FIG. 5 are results of simulations performed under conditions such that the target rotation speed of the motor has been corrected from V0 to V0′. In the simulation results illustrated in FIG. 3 to FIG. 5, when a step-out occurs to prevent a rotation speed V1 of the motor from following the target rotation speed V0of the motor, an attempt is made for correction by limiting motor rotational acceleration, and the target rotation speed V0of the motor is corrected to a target rotation speed V0′ of the motor. This helps prevent occurrence of a step-out in a simulation, and the rotation speed V1 of the motor follows the target rotation speed V0′ of the motor.

In FIG. 4, motor rotation acceleration is restricted more strictly than in FIG. 3. Thus, in FIG. 4, a maximum value of inclination of the target rotation speed V0′ of the motor is smaller than in FIG. 3. As a result, in FIG. 4, a period during which a step-out error index SOE1 transiently becomes large is shorter than in FIG. 3.

In FIG. 5, the motor rotation acceleration is restricted more strictly than in FIG. 4. Thus, in FIG. 5, the maximum value of inclination of the target rotation speed V0′ of the motor is smaller than in FIG. 4. As a result, in FIG. 5, unlike in FIG. 3 and FIG. 4, the period during which the step-out error index SOEI transiently becomes large is zero.

As in the present embodiment, by generating a display signal for displaying the step-out error index, it is possible to visualize whether or not control is being performed with a high possibility of a step-out error. Furthermore, by displaying the simulation result of the operation of the motor control system and the step-out error index on the same screen, it is possible to make it easy for the user to grasp association between the operation of the motor control system and the possibility of a step-out error. Moreover, by displaying the step-out error index in graph form, it is possible to make it easy for the user to grasp the time-based change (change over time) of the step-out error index.

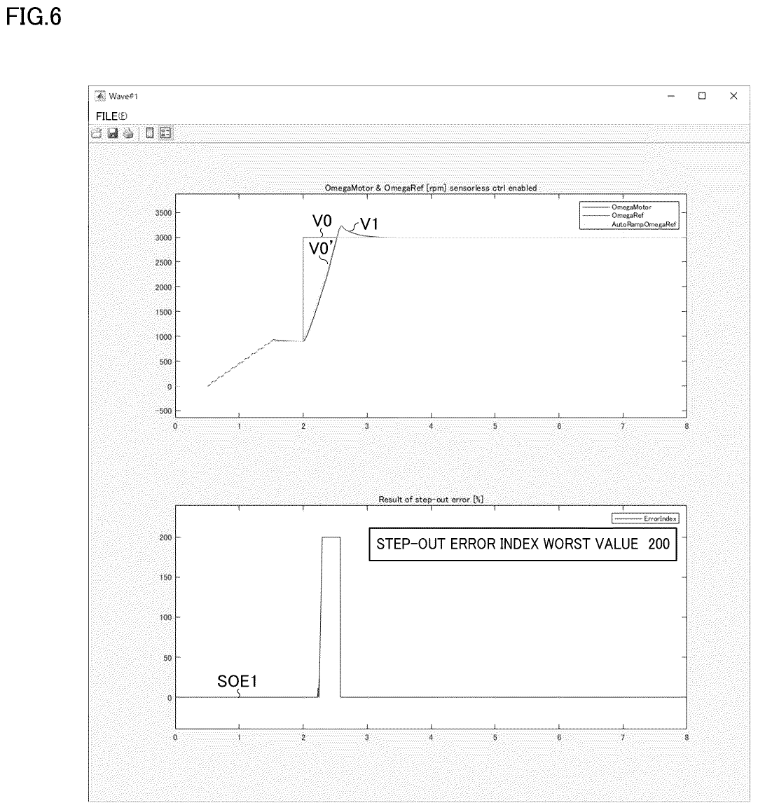

Note that, for example, instead of the first display example illustrated in FIG. 3, a fourth display example illustrated in FIG. 6 may be displayed. The fourth display example shown in FIG. 6 is a display created by adding, to the first display example illustrated in FIG. 3, a value of the step-out error index, more specifically, a worst value of the step-out error index. The value of the step-out index does not need to be displayed together with graph display of the step-out index as in the fourth display example illustrated in FIG. 6, or does not need to be displayed together with graph display of the simulation result and the graph display of the step-error index.

### SUPPLEMENTARY NOTES

Provided below are supplementary notes on the present disclosure of which specific configuration examples have been presented through the embodiments described above.

A simulation program (P1) of the present disclosure is a simulation program that is configured to cause a computer (1) to simulate operation of a motor control system, and that is also configured to cause the computer to generate a display signal for displaying a step-out error index indicating likelihood of the motor control system falling out of step (a first configuration).

In the simulation program having the first configuration described above, the motor control system may be configured to detect a rotation position of a rotor based on an induced voltage generated at a stator coil of a motor (a second configuration).

In the simulation program having the first or second configuration described above, the display signal may be a signal for displaying a simulation result of simulation of operation of the motor control system and the step-out error index on a same screen (a third configuration).

In the simulation program having any one of the first to third configurations described above, the display signal may be a signal for displaying the step-out error index in graph form (a fourth configuration).

What is claimed is:

1. A non-transitory recording medium having a simulation program recorded thereon,
wherein
the simulation program is a program configured to cause a computer to simulate operation of a motor control system and configured to cause the computer to generate a display signal for displaying a step-out error index indicating likelihood of the motor control system falling out of step.

2. The recording medium according to claim 1,
wherein
the motor control system is configured to detect a rotation position of a rotor based on an induced voltage generated at a stator coil of a motor.

3 The recording medium according to claim 1,
wherein
the display signal is a signal for displaying a simulation result of operation of the motor control system and the step-out error index on a same screen.

4. The recording medium according to claim 2,
wherein
the display signal is a signal for displaying a simulation result of operation of the motor control system and the step-out error index on a same screen.

5. The recording medium according to claim 1,
wherein
the display signal is a signal for displaying the step-out error index in graph form.

6. The recording medium according to claim 2,
wherein
the display signal is a signal for displaying the step-out error index in graph form.

7. The recording medium according to claim 3,
wherein
the display signal is a signal for displaying the step-out error index in graph form.

8. The recording medium according to claim 4,
wherein
the display signal is a signal for displaying the step-out error index in graph form.

9. A computer, comprising:
a control unit configured to simulate operation of a motor control system; and
a display unit configured to display a step-out error index indicating likelihood of the motor control system falling out of step.

10. The computer according to claim 9,
wherein
the motor control system is configured to detect a rotation position of a rotor based on an induced voltage generated at a stator coil of a motor.

11. The computer according to claim 9,
wherein
the display unit is configured to display a simulation result of operation of the motor control system and the step-out error index on a same screen.

12. The computer according to claim 10,
wherein
the display unit is configured to display a simulation result of operation of the motor control system and the step-out error index on a same screen.

13. The computer according to claim 9,
wherein
the display unit is configured to display the step-out error index in graph form.

14. The computer according to claim 10,
wherein
the display unit is configured to display the step-out error index in graph form.

15. The computer according to claim 11,
wherein
the display unit is configured to display the step-out error index in graph form.

16. The computer according to claim 12,
wherein
the display unit is configured to display the step-out error index in graph form.
